(19) United States
(12) Patent Application Publication
(10) Pub. No.: US 2024/0110719 A1
(43) Pub. Date: Apr. 4, 2024

(54) AIR CONDITIONING CONTROL DEVICE AND AIR CONDITIONING CONTROL METHOD

(71) Applicant: MITSUBISHI ELECTRIC CORPORATION, Tokyo (JP)

(72) Inventors: Hiroaki HOKARI, Tokyo (JP); Koki NAKANE, Tokyo (JP); Toshisada MARIYAMA, Tokyo (JP); Naoyuki MIYAZAKI, Tokyo (JP); Osamu HASEGAWA, Tokyo (JP); Wataru BABA, Tokyo (JP)

(73) Assignee: MITSUBISHI ELECTRIC CORPORATION, Tokyo (JP)

(21) Appl. No.: 18/532,250

(22) Filed: Dec. 7, 2023

Related U.S. Application Data
(63) Continuation of application No. PCT/JP2022/021873, filed on May 30, 2022.

(30) Foreign Application Priority Data
Jul. 30, 2021 (JP) 2021-125605

(51) Int. Cl. F24F 11/65; F24F 11/49; F24F 11/64

(52) U.S. Cl. CPC F24F 11/65; F24F 11/49; F24F 11/64; F24F 2110/10

(57) ABSTRACT

An air conditioning control device includes: an operation pattern acquiring unit to acquire operation patterns indicating an operation target air conditioner in a room; a temperature data acquiring unit to acquire temperature data indicating a temperature measured by a temperature sensor when the air conditioner is in operation: a prediction model generating unit to generate, using a control amount of the air conditioner and temperature data acquired when the air conditioner is in operation as training data, a room-temperature prediction model for predicting the temperature measured by the temperature sensor when the air conditioner are in operation; and an operation pattern selecting unit to provide the control amount of the air conditioner to the room-temperature prediction model to acquire a prediction temperature from each of the room-temperature prediction models, and selects one operation pattern from the operation patterns on the basis of the prediction temperature.

### CROSS REFERENCE TO RELATED APPLICATIONS

This application is a Continuation of PCT International Application No. PCT/JP2022/021873 filed on May 30, 2022, which claims priority under 35 U.S.C. 119(a) to Patent Application No. 2021-125605, filed in Japan on Jul. 30, 2021, all of which are hereby expressly incorporated by reference into the present application.

### TECHNICAL FIELD

The present disclosure relates to an air conditioning control device and an air conditioning control method.

### BACKGROUND ART

A plurality of electronic devices is installed in a data center, a server room, or the like. The electronic devices include computers, communication devices, or the like. A plurality of air conditioners is installed in the data center or the like in order to suppress an increase in indoor temperature due to heat generated from the electronic devices. When some air conditioners among the plurality of air conditioners installed in the data center or the like are operated, the temperature of the data center or the like may be maintained at a certain temperature or lower. In order to suppress the power consumption of the air conditioners, it is desirable that the number of air conditioners to be actually operated is small. An air conditioner that is not actually operated is used as a backup machine.

Some air conditioning control devices that control a plurality of air conditioners installed in a server room can determine one or more air conditioners to be actually operated among the plurality of air conditioners (hereinafter referred to as “conventional air conditioning control device”, see Patent Literature 1). The conventional air conditioning control device acquires layout data indicating a position of a hot aisle that is a path through which high-temperature air discharged from electronic devices passes and positions of a plurality of air conditioners. Then, the conventional air conditioning control device determines one or more air conditioners to be actually operated among the plurality of air conditioners on the basis of the layout data.

### CITATION LIST

### Patent Literatures

Patent Literature 1: JP 2018-005646 A

### SUMMARY OF INVENTION

### Technical Problem

The conventional air conditioning control device has a problem that, if the layout data cannot be acquired, it is impossible to determine one or more air conditioners to be actually operated among the plurality of air conditioners installed in the server room.

The present disclosure has been made to solve the above problem, and an object thereof is to obtain an air conditioning control device and an air conditioning control method with which it is possible to determine one or more air conditioners to be actually operated among a plurality of air conditioners without acquiring layout data.

### Solution to Problem

An air conditioning control device according to the present disclosure includes processing circuitry to acquire a plurality of operation patterns each indicating at least one operation target air conditioner among a plurality of air conditioners installed in a room, to acquire temperature data indicating a measurement temperature of a temperature sensor installed in the room when the at least one operation target air conditioner indicated by each of the plurality of operation patterns is in operation, to generate, using a control amount of the at least one operation target air conditioner indicated by each of the plurality of operation patterns and the temperature data when the at least one operation target air conditioner is in operation as training data, a room-temperature prediction model, which corresponds to each of the plurality of operation patterns, for predicting a temperature measured by the temperature sensor when the at least one operation target air conditioner indicated by each of the plurality of operation patterns is in operation, and to acquire a prediction temperature from the room-temperature prediction model by providing the control amount of the at least one operation target air conditioner indicated by each of the plurality of operation patterns to the room-temperature prediction model, and selects one operation pattern from the plurality of operation patterns on a basis of the prediction temperature.

### Advantageous Effects of Invention

According to the present disclosure, it is possible to determine one or more air conditioners to be actually operated among a plurality of air conditioners without acquiring layout data.

### BRIEF DESCRIPTION OF DRAWINGS

FIG. 1 is a configuration diagram illustrating an air conditioning system including an air conditioning control device 3 according to a first embodiment.

FIG. 2 is a hardware configuration diagram illustrating hardware of the air conditioning control device 3 according to the first embodiment.

FIG. 3 is a hardware configuration diagram of a computer in a case where the air conditioning control device 3 is implemented by software, firmware, or the like.

FIG. 4 is a flowchart illustrating an air conditioning control method which is a processing procedure performed by the air conditioning control device 3.

FIG. 5 is a flowchart illustrating a part of the processing procedure performed by the air conditioning control device 3.

FIG. 6 is a configuration diagram illustrating an air conditioning system including an air conditioning control device 3 according to a second embodiment.

FIG. 7 is a hardware configuration diagram illustrating hardware of the air conditioning control device 3 according to the second embodiment.

FIG. 8 is an explanatory diagram illustrating candidates for a set temperature PTₖ determined by a set temperature determining unit 18.

FIG. 9 is an explanatory diagram illustrating accuracy of a room-temperature prediction model RTM_{g} with respect to a set temperature PTₖ.

### DESCRIPTION OF EMBODIMENTS

In order to describe the present disclosure in more detail, some modes for carrying out the present disclosure will now be described with reference to the accompanying drawings.

### First Embodiment

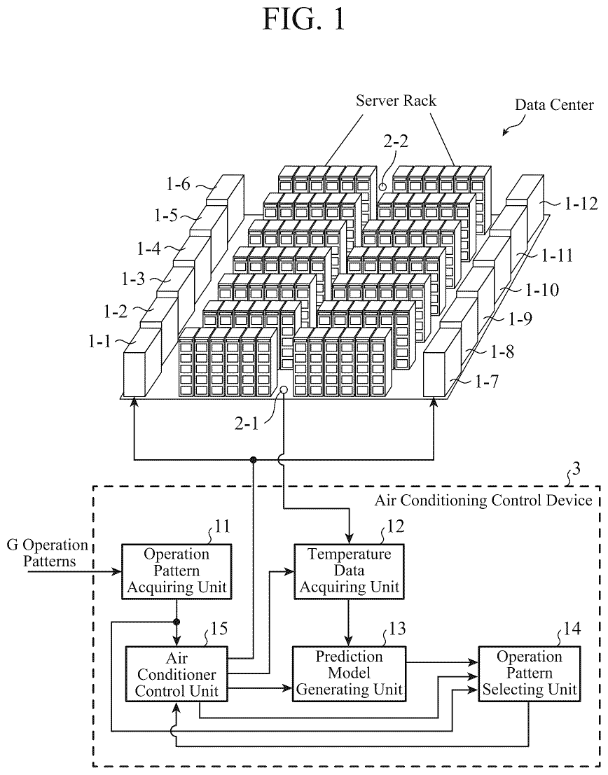

FIG. 1 is a configuration diagram illustrating an air conditioning system including an air conditioning control device 3 according to a first embodiment.

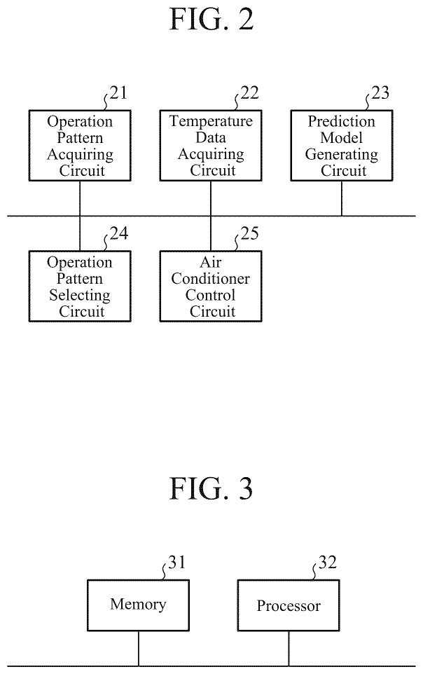

FIG. 2 is a hardware configuration diagram illustrating hardware of the air conditioning control device 3 according to the first embodiment.

The air conditioning system illustrated in FIG. 1 is a system that manages a temperature in a room in which electronic devices are installed. The electronic devices include computers, communication devices, or the like. Examples of the room managed by the air conditioning system include a data center and a server room.

The air conditioning system illustrated in FIG. 1 includes N air conditioners 1-1 to 1-N, M temperature sensors 2-1 to 2-M, and the air conditioning control device 3. Each of N and M is an integer equal to or greater than 2.

A plurality of server racks is disposed in a data center or the like, and each of the server racks houses a plurality of electronic devices. In the example of FIG. 1, 14 server racks are disposed.

The air conditioners 1-1 to 1-N are installed in the data center or the like. In the example of FIG. 1, N=12.

The temperature sensors 2-1 to 2-M are installed in the data center or the like. FIG. 1 illustrates an example in which M=2 for simplification of the drawing. In practice, temperature sensors 2-m (m=1, . . . , M) are installed at intervals of several meters. In addition, the temperature sensors 2-m are installed, for example, at a position 1.5 m above and at a position 2.5 m above the floor of the data center or the like.

Each of the temperature sensors 2-m (m=1, . . . , M) measures a temperature at a position where the temperature sensor is installed in the data center or the like, and outputs temperature data indicating a measurement temperature MTₘ to the air conditioning control device 3.

The air conditioning control device 3 includes an operation pattern acquiring unit 11, a temperature data acquiring unit 12, a prediction model generating unit 13, an operation pattern selecting unit 14, and an air conditioner control unit 15.

The operation pattern acquiring unit 11 is implemented by, for example, an operation pattern acquiring circuit 21 illustrated in FIG. 2.

The operation pattern acquiring unit 11 acquires G operation patterns OP₁ to OP_{G} each indicating operation target air conditioners 1-k among the N air conditioners 1-1 to 1-N.

The number G of the operation patterns OP acquired by the operation pattern acquiring unit 11 is, for example, the number of combinations _{N}C_{P} of selecting P or more air conditioners 1 from N air conditioners 1-1 to 1-N, and P is an integer not less than 1 but less than N.

When the operation target air conditioners are, for example, the air conditioners 1-3, 1-5, 1-8, and 1-10, k=3, 5, 8, and 10. When the operation target air conditioners are, for example, the air conditioners 1-4, 1-7, and 1-9, k=4, 7, and 9.

The operation pattern acquiring unit 11 outputs the G operation patterns OP₁ to OP_{G} to each of the operation pattern selecting unit 14 and the air conditioner control unit 15.

In the air conditioning system illustrated in FIG. 1, the operation pattern acquiring unit 11 acquires the operation pattern OP_{g} (g=1, . . . , G) from the outside of the air conditioning control device 3. However, this is merely an example, and the operation pattern acquiring unit 11 may acquire the operation pattern OP_{g} from, for example, a storage device (not illustrated) of the air conditioning control device 3.

The temperature data acquiring unit 12 is implemented by, for example, a temperature data acquiring circuit 22 illustrated in FIG. 2.

The temperature data acquiring unit 12 acquires temperature data indicating a measurement temperature MTₘ which is a temperature measured by the temperature sensor 2-m (m=1, . . . , M) when the operation target air conditioner 1-k indicated by each operation pattern OP_{g} is in operation.

The temperature data acquiring unit 12 outputs the acquired temperature data indicating the measurement temperature MTₘ to the prediction model generating unit 13.

The prediction model generating unit 13 is implemented by, for example, a prediction model generating circuit 23 illustrated in FIG. 2.

The prediction model generating unit 13 acquires the temperature data indicating the measurement temperature MTₘ from the temperature data acquiring unit 12, and acquires a control amount of the operation target air conditioner 1-k indicated by the operation pattern OP_{g} from the air conditioner control unit 15.

As the control amount of the operation target air conditioner 1-k, for example, the set temperature of the air conditioner 1-k, the air volume of the air conditioner 1-k, or the frequency of the operating voltage of a compressor connected to the air conditioner 1-k is conceivable. In the following description, the control amount of the air conditioner 1-k is the set temperature of the air conditioner 1-k in the air conditioning system illustrated in FIG. 1.

The prediction model generating unit 13 uses, as training data, the set temperature PTₖ of the operation target air conditioner 1-k indicated by the operation pattern OP_{g} (g=1, . . . , G) and the temperature data acquired by the temperature data acquiring unit 12 when the operation target air conditioner is operating, to generate a room-temperature prediction model RTM_{g} for predicting the temperature to be measured by the temperature sensor 2-m (m=1, . . . , M) when the operation target air conditioner 1-k indicated by the operation pattern OP_{g} is operating.

The prediction model generating unit 13 outputs the generated G room-temperature prediction models RTM₁ to RTM_{G} to the operation pattern selecting unit 14.

The operation pattern selecting unit 14 is implemented by, for example, an operation pattern selecting circuit 24 illustrated in FIG. 2.

The operation pattern selecting unit 14 acquires the G operation patterns OP₁ to OP_{G} from the operation pattern acquiring unit 11, and acquires the G room-temperature prediction models RTM₁ to RTM_{G} from the prediction model generating unit 13.

In addition, the operation pattern selecting unit 14 acquires the set temperature PTₖ of the operation target air conditioner 1-k indicated by the operation pattern OP_{g} from the air conditioner control unit 15.

The operation pattern selecting unit 14 provides the set temperature PTₖ that is the control amount of the operation target air conditioner 1-k indicated by the operation pattern OP_{g} to the room-temperature prediction model RTM_{g} (g=1, . . . , G) to acquire a prediction temperature FT_{g} from the room-temperature prediction model RTM_{g}.

The operation pattern selecting unit 14 selects one operation pattern OP_{SEL} from among the G operation patterns OP₁ to OP_{G} on the basis of the prediction temperature FT_{g} (g=1, . . . , G).

The operation pattern selecting unit 14 outputs the selected one operation pattern OP_{SEL} to the air conditioner control unit 15.

The air conditioner control unit 15 is implemented by, for example, an air conditioner control circuit 25 illustrated in FIG. 2.

The air conditioner control unit 15 acquires the G operation patterns OP₁ to OP_{G} from the operation pattern acquiring unit 11.

The air conditioner control unit 15 operates the operation target air conditioner 1-k indicated by the operation pattern OP_{g} at the set temperature PTₖ in order to cause the prediction model generating unit 13 to generate the G room-temperature prediction models RTM₁ to RTM_{G}. For example, suppose G=3. In this case, the air conditioner control unit 15 repeatedly performs an operation of the operation target air conditioner 1-k indicated by the operation pattern OP₁ at the set temperature PTₖ for a certain period of time, and then, after the indoor temperature returns to the temperature before the activation of the operation target air conditioner 1-k, operating again the operation target air conditioner 1-k indicated by the operation pattern OP₁ at the set temperature PTₖ for a certain period of time.

Thereafter, the air conditioner control unit 15 repeatedly performs an operation of the operation target air conditioner 1-k indicated by the operation pattern OP₂ at the set temperature PTₖ for a certain period of time, and then, after the indoor temperature returns to the temperature before the activation of the operation target air conditioner 1-k, performs again an operation of the operation target air conditioner 1-k indicated by the operation pattern OP₂ at the set temperature PTₖ for a certain period of time.

Thereafter, the air conditioner control unit 15 repeatedly performs an operation of the operation target air conditioner 1-k indicated by the operation pattern OP_{g} at the set temperature PTₖ for a certain period of time, and then, after the indoor temperature returns to the temperature before the activation of the operation target air conditioner 1-k, performs again an operation of the operation target air conditioner 1-k indicated by the operation pattern OP_{g} at the set temperature PTₖ for a certain period of time.

When operating the operation target air conditioner 1-k at the set temperature PTₖ, the air conditioner control unit 15 outputs the set temperature PTₖ of the air conditioner 1-k to each of the prediction model generating unit 13 and the operation pattern selecting unit 14.

The set temperature PTₖ of the operation target air conditioner 1-k may be stored in an internal memory of the air conditioner control unit 15 or may be given from the outside of the air conditioning control device 3.

The air conditioner control unit 15 operates the operation target air conditioner 1-k indicated by the operation pattern OP_{SEL} selected by the operation pattern selecting unit 14 at the set temperature PTₖ.

FIG. 1 illustrates an example in which each of the operation pattern acquiring unit 11, the temperature data acquiring unit 12, the prediction model generating unit 13, the operation pattern selecting unit 14, and the air conditioner control unit 15, which are components of the air conditioning control device 3, is implemented by dedicated hardware as illustrated in FIG. 2. That is, it is assumed that the air conditioning control device 3 is implemented by the operation pattern acquiring circuit 21, the temperature data acquiring circuit 22, the prediction model generating circuit 23, the operation pattern selecting circuit 24, and the air conditioner control circuit 25.

Here, each of the operation pattern acquiring circuit 21, the temperature data acquiring circuit 22, the prediction model generating circuit 23, the operation pattern selecting circuit 24, and the air conditioner control circuit 25 is, for example, a single circuit, a composite circuit, a programmed processor, a parallel programmed processor, an application specific integrated circuit (ASIC), a field-programmable gate array (FPGA), or a combination of some of these circuits.

The components of the air conditioning control device 3 are not limited to be implemented by dedicated hardware, and the air conditioning control device 3 may be implemented by software, firmware, or a combination of software and firmware.

Software or firmware is stored in a memory of a computer as a program. The computer means hardware that executes the program, and may be, for example, a central processing unit (CPU), a central processor, a processing unit, a computing unit, a microprocessor, a microcomputer, a processor, or a digital signal processor (DSP).

FIG. 3 is a hardware configuration diagram of a computer in a case where the air conditioning control device 3 is implemented by software, firmware, or the like.

In a case where the air conditioning control device 3 is implemented by software, firmware, or the like, a program for causing the computer to execute the processing procedures performed in the operation pattern acquiring unit 11, the temperature data acquiring unit 12, the prediction model generating unit 13, the operation pattern selecting unit 14, and the air conditioner control unit 15 is stored in a memory 31. Then, a processor 32 of the computer executes the program stored in the memory 31.

Further, FIG. 2 shows an example in which each of the components of the air conditioning control device 3 is implemented by dedicated hardware, and FIG. 3 shows an example in which the air conditioning control device 3 is implemented by software, firmware, or the like. However, this is merely an example, and some components in the air conditioning control device 3 may be implemented by dedicated hardware, and the remaining components may be implemented by software, firmware, or the like.

Next, the operation of the air conditioning system illustrated in FIG. 1 will be described.

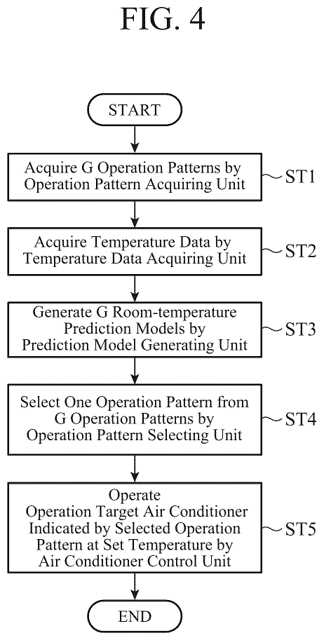

FIG. 4 is a flowchart illustrating an air conditioning control method which is a processing procedure performed by the air conditioning control device 3.

The operation pattern acquiring unit 11 acquires G operation patterns OP₁ to OP_{G} indicating the operation target air conditioners 1-k from outside the air conditioning control device 3 (step ST1 in FIG. 4).

The operation pattern acquiring unit 11 outputs the G operation patterns OP₁ to OP_{G} to each of the operation pattern selecting unit 14 and the air conditioner control unit 15.

The air conditioner control unit 15 acquires the G operation patterns OP₁ to OP_{G} from the operation pattern acquiring unit 11.

The air conditioner control unit 15 operates the operation target air conditioner 1-k indicated by each operation pattern OP_{g} at the set temperature PTₖ in order to cause the prediction model generating unit 13 to generate the G room-temperature prediction models RTM₁ to RTM_{G}.

For example, suppose that G=2, the operation target air conditioner 1-k indicated by the operation pattern OP₁ is the air conditioners 1-3 and 1-8, and the operation target air conditioner 1-k indicated by the operation pattern OP₂ is the air conditioners 1-5 and 1-10. Further, suppose that the set temperatures PTₖ of all the operation target air conditioners 1-k are 19 degrees, and the temperature of the room in which the electronic devices such as a computer are installed is 25 degrees.

In this case, the air conditioner control unit 15 operates the operation target air conditioners 1-3 and 1-8 indicated by the operation pattern OP₁ at the set temperature PTₖ (=19 degrees) for a certain period of time. The certain period of time is, for example, 1 hour or 1.5 hours.

The air conditioner control unit 15 operates the operation target air conditioners 1-3 and 1-8 at the set temperature PTₖ for a certain period of time, and then, after the indoor temperature returns to 25 degrees which is the temperature before the air conditioners 1-3 and 1-8 are operated, operates the operation target air conditioners 1-3 and 1-8 indicated by the operation pattern OP₁ at the set temperature PTₖ (=19 degrees) for a certain period of time.

The air conditioner control unit 15 operates the operation target air conditioners 1-3 and 1-8 indicated by the operation pattern OP₁ Q times, for example. Q is an integer equal to or greater than 2.

Thereafter, when the indoor temperature returns to 25 degrees which is the temperature before the air conditioners 1-3 and 1-8 are operated, the air conditioner control unit 15 operates the operation target air conditioners 1-5 and 1-10 indicated by the operation pattern OP₂ at the set temperature PTₖ (=19 degrees) for a certain period of time.

When the indoor temperature returns to 25 degrees which is the temperature before the air conditioners 1-5 and 1-10 are operated after the operation target air conditioners 1-5 and 1-10 are operated, the air conditioner control unit 15 operates the operation target air conditioners 1-5 and 1-10 indicated by the operation pattern OP₂ at the set temperature PTₖ (=19 degrees) for a certain period of time.

The air conditioner control unit 15 operates the operation target air conditioners 1-5 and 1-10 indicated by the operation pattern OP₂ Q times, for example.

When operating the operation target air conditioner 1-k at the set temperature PTₖ, the air conditioner control unit 15 outputs the set temperature PTₖ of the air conditioner 1-k to each of the prediction model generating unit 13 and the operation pattern selecting unit 14. In addition, the air conditioner control unit 15 outputs a request to generate the room-temperature prediction model RTM_{g} corresponding to each operation pattern OP_{g} to the prediction model generating unit 13.

The air conditioner control unit 15 outputs, to the temperature data acquiring unit 12, a data acquisition request to instruct acquisition of temperature data for a certain period of time after the operation target air conditioner 1-k starts operation.

When receiving the data acquisition request from the air conditioner control unit 15, the temperature data acquiring unit 12 acquires temperature data indicating the measurement temperature MTₘ of the temperature sensor 2-m (m=1, . . . , M) (step ST2 in FIG. 4).

For example, when G=2 and the air conditioner control unit 15 has operated the operation target air conditioners 1-3 and 1-8 indicated by the operation pattern OPt Q times at the set temperature PTₖ, the temperature data acquiring unit 12 acquires temperature data indicating the measurement temperature MTₘ which is the temperature measured by the temperature sensor 2-m during operation of each of the air conditioners 1-3 and 1-8. Therefore, the temperature data acquiring unit 12 acquires Q pieces of temperature data when the operation target air conditioners 1-3 and 1-8 indicated by the operation pattern OP₁ are operated.

In addition, when the air conditioner control unit 15 has operated the operation target air conditioners 1-5 and 1-10 indicated by the operation pattern OP₂ Q times at the set temperature PTₖ, the temperature data acquiring unit 12 acquires temperature data indicating the measurement temperature MTₘ which is the temperature measured by the temperature sensor 2-m during operation of each of the air conditioners 1-5 and 1-10. Therefore, the temperature data acquiring unit 12 acquires Q pieces of temperature data when the operation target air conditioners 1-5 and 1-10 indicated by the operation pattern OP₂ are operated.

The temperature data acquiring unit 12 outputs the acquired G×Q pieces of temperature data indicating the measurement temperature MTₘ to the prediction model generating unit 13.

The prediction model generating unit 13 acquires G×Q pieces of temperature data from the temperature data acquiring unit 12.

The prediction model generating unit 13 acquires, from the air conditioner control unit 15, the set temperature PTₖ of the operation target air conditioner 1-k indicated by the operation pattern OP_{g} (g=1, . . . . , G) and the request to generate the room-temperature prediction model RTM_{g} corresponding to the operation pattern OP_{g}.

When acquiring the request to generate the room-temperature prediction model RTM_{g}, the prediction model generating unit 13 prepares a data set including the set temperature PTₖ of the operation target air conditioner 1-k indicated by the operation pattern OP_{g} and the qth (q=1, . . . , Q) temperature data among the Q pieces of temperature data as Q pieces of training data to be provided to each room-temperature prediction model RTM_{g}.

First data set=set temperature PTₖ of air conditioner 1-k+first temperature data

Second data set=set temperature PTₖ of air conditioner 1-k+second temperature data

Qth data set=set temperature PTₖ of air conditioner 1-k+Qth temperature data

The prediction model generating unit 13 provides the first data set to the untrained room-temperature prediction model RTM_{g}, and performs training to change the internal parameter of the room-temperature prediction model RTM_{g} in such a way that a prediction temperature FT_{g} output from the room-temperature prediction model RTM_{g} approaches the measurement temperature MTₘ indicated by the first temperature data.

Next, the prediction model generating unit 13 provides the second data set to the room-temperature prediction model RTM_{g} which has been trained by the first data set, and performs training to change the internal parameter of the room-temperature prediction model RTM_{g} in such a way that the prediction temperature FT_{g} output from the room-temperature prediction model RTM_{g} approaches the measurement temperature MTₘ indicated by the second temperature data.

Thereafter, the prediction model generating unit 13 provides the qth (q=3, . . . , Q) data set to the room-temperature prediction model RTM_{g} which has been trained by the (q−1)th data set, and performs training to change the internal parameter of the room-temperature prediction model RTM_{g} in such a way that the prediction temperature FT_{g} output from the room-temperature prediction model RTM_{g} approaches the measurement temperature MTₘ indicated by the qth temperature data.

As described above, the prediction model generating unit 13 generates the room-temperature prediction model RTM_{g} (g=1, . . . , G) corresponding to each of the G operation patterns OP₁ to OP_{G}, (step ST3 in FIG. 4).

The room-temperature prediction model RTM_{g} may be any machine learning model that can output the prediction temperature FT_{g} of the temperature measured by the temperature sensor 2-m after a certain period of time when receiving the set temperature PTₖ of the operation target air conditioner 1-k, and may be of any type of prediction model. Examples of the room-temperature prediction model RTM_{g} include a linear regression model, a gradient boosting tree, and a neural network.

A process for generating the room-temperature prediction model RTM_{g} is a known technique, and thus, the detailed description thereof will be omitted.

The prediction model generating unit 13 outputs the generated G room-temperature prediction models RTM₁ to RTM_{G} to the operation pattern selecting unit 14.

Here, the prediction model generating unit 13 generates the room-temperature prediction model RTM_{g} using Q data sets as training data. However, this is merely an example. The prediction model generating unit 13 may prepare Q data sets each including the power consumption and the like of all the electronic devices installed in the data center and the like, and may generate the room-temperature prediction model RTM_{g} using Q data sets including the power consumption and the like of the electronic devices as the training data.

The operation pattern selecting unit 14 acquires the G operation patterns OP₁ to OP_{G} from the operation pattern acquiring unit 11, and acquires the G room-temperature prediction models RTM₁ to RTM_{G} from the prediction model generating unit 13.

In addition, the operation pattern selecting unit 14 acquires the set temperature PTₖ of the operation target air conditioner 1-k indicated by the operation pattern OP_{g} from the air conditioner control unit 15.

The operation pattern selecting unit 14 gives the set temperature PTₖ to each of the G room-temperature prediction models RTM₁ to RTM_{G}, and acquires the prediction temperature FT_{g} from the room-temperature prediction model RTM_{g} (g=1, . . . . , G).

The operation pattern selecting unit 14 selects one operation pattern OP_{SEL} from among the G operation patterns OP₁ to OP_{G} on the basis of the prediction temperature FT_{g} (g=1, . . . , G) (step ST4 in FIG. 4).

The operation pattern selecting unit 14 outputs the selected one operation pattern OP_{SEL} to the air conditioner control unit 15.

For example, the operation pattern selecting unit 14 tentatively selects, from among the G operation patterns OP₁ to OP_{G}, an operation pattern in which the prediction temperature FT_{g} obtained from the corresponding room-temperature prediction model RTM_{g} (g=1, . . . , G) is equal to or less than a temperature upper limit value Tₘₐₓ, and the prediction accuracy of the corresponding room-temperature prediction model RTM_{g} is within a threshold. The temperature upper limit value Tₘₐₓ is the highest possible indoor temperature that does not affect the electronic device, and is several degrees higher than the set temperature PTₖ. The temperature upper limit value Tₘₐₓ may be stored in the internal memory of the operation pattern selecting unit 14 or may be given from the outside of the air conditioning control device 3.

The prediction accuracy of the room-temperature prediction model RTM_{g} is output from the room-temperature prediction model RTM_{g}. The threshold may be 1.5 degrees, 2 degrees, or the like. Therefore, when the threshold is, for example, 1.5 degrees, the room-temperature prediction model RTM_{g} whose prediction accuracy is within 1.5 degrees is selected. The threshold may be stored in the internal memory of the operation pattern selecting unit 14 or may be given from the outside of the air conditioning control device 3.

The operation pattern selecting unit 14 selects one operation pattern in which the number of operation target air conditioners 1-k is relatively small from among one or more operation patterns tentatively selected. That is, the operation pattern selecting unit 14 selects the operation pattern in which the number of operation target air conditioners 1-k is the smallest as the operation pattern OP_{SEL} from among the one or more operation patterns tentatively selected.

The air conditioner control unit 15 acquires the operation pattern OP_{SEL} from the operation pattern selecting unit 14.

The air conditioner control unit 15 operates the operation target air conditioner 1-k indicated by the operation pattern OP_{SEL} at the set temperature PTₖ (step ST5 in FIG. 4).

In the first embodiment described above, the air conditioning control device 3 includes: the operation pattern acquiring unit 1 to acquire a plurality of operation patterns indicating an operation target air conditioner 1-k among a plurality of air conditioners 1-1 to 1-N installed in a room; and the temperature data acquiring unit 12 to acquire temperature data indicating measurement temperatures of the temperature sensors 2-1 to 2-M installed in the room when the operation target air conditioner 1-k indicated by each of the operation patterns is in operation. The air conditioning control device 3 also includes the prediction model generating unit 13 to generate, using a control amount of the operation target air conditioner 1-k indicated by each of the operation patterns and temperature data acquired by the temperature data acquiring unit 12 when the operation target air conditioner 1-k is in operation as training data, a room-temperature prediction model for predicting the temperatures measured by the temperature sensors 2-1 to 2-M when the operation target air conditioner 1-k indicated by each of the operation patterns is in operation. The air conditioning control device 3 further includes the operation pattern selecting unit 14 to provide the control amount of the operation target air conditioner 1-k indicated by each of the operation patterns to room-temperature prediction models corresponding to the respective operation patterns, generated by the prediction model generating unit 13, acquire a prediction temperature from each of the room-temperature prediction models, and selects one operation pattern from the plurality of operation patterns on the basis of the prediction temperature.

Accordingly, the air conditioning control device 3 can determine the air conditioner 1-k to be actually operated among the plurality of air conditioners 1-1 to 1-N without acquiring layout data.

In the air conditioning control device 3 illustrated in FIG. 1, the prediction model generating unit 13 generates the G room-temperature prediction models RTM₁ to RTM_{G}, and then, the operation pattern selecting unit 14 selects one operation pattern OP_{SEL} from the operation patterns OP_{g} corresponding to the respective G room-temperature prediction models RTM₁ to RTM_{G}.

However, this is merely an example, and the operation pattern selecting unit 14 may select one operation pattern OP_{SEL} as follows.

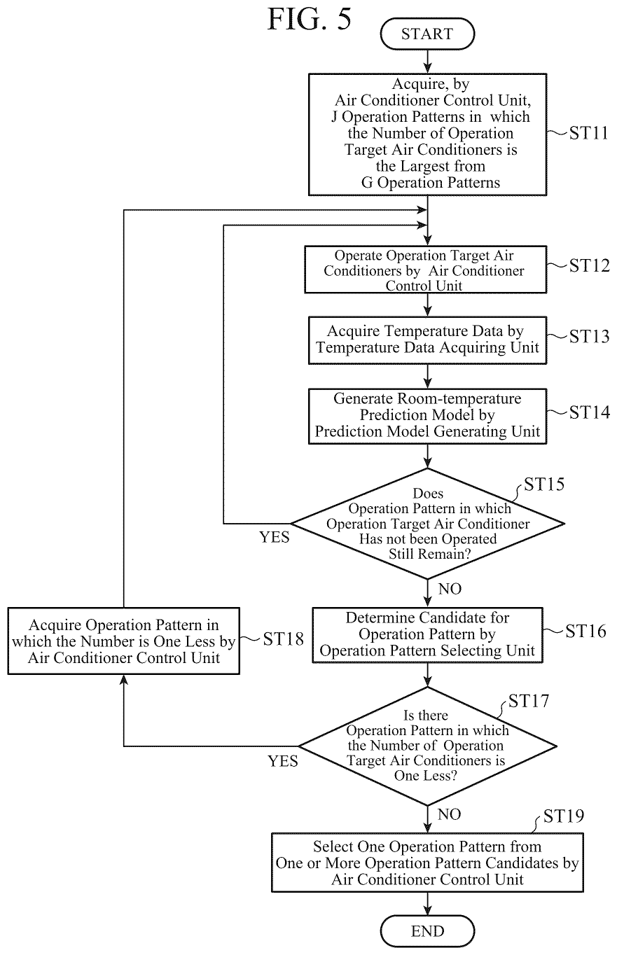

FIG. 5 is a flowchart illustrating a part of the processing procedure performed by the air conditioning control device 3.

First, the air conditioner control unit 15 acquires J operation patterns OPⱼ (j=1, . . . , J) having the largest number of operation target air conditioners 1-k from among the G operation patterns OP₁ to OP_{G} (step ST11 in FIG. 5). J≤G is established. For example, in a case where the largest number is (N−3), and there are J operation patterns OPⱼ having (N−3) operation target air conditioners 1-k, the air conditioner control unit 15 acquires J operation patterns OPⱼ. J is an integer equal to or greater than 1 and equal to or less than G. The operation pattern OP_{R} and the operation pattern OPⱼ are basically different from each other.

The air conditioner control unit 15 operates the operation target air conditioner 1-k indicated by the operation pattern OPⱼ out of the J operation patterns OP₁ to OP_{J} at the set temperature PTₖ for a certain period of time (step ST12 in FIG. 5). The air conditioner control unit 15 operates the operation target air conditioner 1-k indicated by the operation pattern OPⱼ Q times, for example.

When operating the operation target air conditioner 1-k at the set temperature PTₖ, the air conditioner control unit 15 outputs the set temperature PTₖ of the air conditioner 1-k to each of the prediction model generating unit 13 and the operation pattern selecting unit 14. In addition, the air conditioner control unit 15 outputs a request to generate a room-temperature prediction model RTMⱼ corresponding to the operation pattern OPⱼ to the prediction model generating unit 13.

When operating the operation target air conditioner 1-k, the air conditioner control unit 15 outputs a data acquisition request to the temperature data acquiring unit 12.

When receiving the data acquisition request from the air conditioner control unit 15, the temperature data acquiring unit 12 acquires Q pieces of temperature data indicating the measurement temperature MTₘ of the temperature sensor 2-m (m=1, . . . , M) (step ST13 in FIG. 5).

The temperature data acquiring unit 12 outputs the acquired Q pieces of temperature data to the prediction model generating unit 13.

The prediction model generating unit 13 acquires, from the temperature data acquiring unit 12. Q pieces of temperature data when the operation target air conditioner 1-k indicated by the operation pattern OPⱼ is operated at the set temperature PTₖ.

The prediction model generating unit 13 acquires, from the air conditioner control unit 15, the set temperature PTₖ of the operation target air conditioner 1-k indicated by the operation pattern OPⱼ and a request to generate the room-temperature prediction model RTMⱼ corresponding to the operation pattern OPⱼ.

When acquiring the request to generate the room-temperature prediction model RTMⱼ, the prediction model generating unit 13 prepares the above-described Q data sets from the Q pieces of temperature data and the set temperature PTₖ.

The prediction model generating unit 13 sequentially provides the data sets to the room-temperature prediction model RTMⱼ, and repeatedly performs training to change the internal parameter of the room-temperature prediction model RTMⱼ in such a way that a prediction temperature FTⱼ output from the room-temperature prediction model RTMⱼ approaches the measurement temperature MTₘ indicated by the temperature data.

Here, the prediction model generating unit 13 provides Q data sets to the room-temperature prediction model RTMⱼ. However, this is merely an example, and the prediction model generating unit 13 may not provide all the data sets to the room-temperature prediction model RTMⱼ when the prediction accuracy of the room-temperature prediction model RTMⱼ reaches or is beyond the threshold before providing the Q data sets to the room-temperature prediction model RTMⱼ.

The prediction model generating unit 13 continues the machine learning of the room-temperature prediction model RTMⱼ by repeatedly providing the data sets to the room-temperature prediction model RTMⱼ, to thereby generate the room-temperature prediction model RTMⱼ having the prediction accuracy equal to or higher than the threshold (step ST14 in FIG. 5).

The prediction model generating unit 13 outputs the room-temperature prediction model RTMⱼ having the prediction accuracy equal to or higher than the threshold to the operation pattern selecting unit 14.

If an operation pattern OPⱼ in which the operation target air conditioner 1-k has not yet been operated still remains in the acquired J operation patterns OP₁ to OP_{J} (YES in step ST15 in FIG. 5), the air conditioner control unit 15 operates the operation target air conditioner 1-k indicated by the operation pattern OPⱼ in which the operation target air conditioner 1-k has not yet been operated at the set temperature PTₖ for a certain period of time (step ST12 in FIG. 5). The air conditioner control unit 15 operates the operation target air conditioner 1-k indicated by the operation pattern OPⱼ Q times, for example.

When operating the operation target air conditioner 1-k at the set temperature PTₖ, the air conditioner control unit 15 outputs the set temperature PTₖ of the air conditioner 1-k to each of the prediction model generating unit 13 and the operation pattern selecting unit 14. In addition, the air conditioner control unit 15 outputs a request to generate a room-temperature prediction model RTMⱼ corresponding to the operation pattern OPⱼ to the prediction model generating unit 13.

When operating the operation target air conditioner 1-k, the air conditioner control unit 15 outputs a data acquisition request to the temperature data acquiring unit 12.

When receiving the data acquisition request from the air conditioner control unit 15, the temperature data acquiring unit 12 acquires Q pieces of temperature data indicating the measurement temperature MTₘ of the temperature sensor 2-m (m=1, . . . , M) (step ST13 in FIG. 5).

The temperature data acquiring unit 12 outputs the acquired Q pieces of temperature data to the prediction model generating unit 13.

The prediction model generating unit 13 acquires, from the temperature data acquiring unit 12, Q pieces of temperature data when the operation target air conditioner 1-k indicated by the operation pattern OPⱼ is operated at the set temperature PTₖ.

The prediction model generating unit 13 acquires, from the air conditioner control unit 15, the set temperature PTₖ of the operation target air conditioner 1-k indicated by the operation pattern OPⱼ and a request to generate the room-temperature prediction model RTMⱼ corresponding to the operation pattern OPⱼ.

When acquiring the request to generate the room-temperature prediction model RTMⱼ, the prediction model generating unit 13 prepares the above-described Q data sets from the Q pieces of temperature data and the set temperature PTₖ.

The prediction model generating unit 13 sequentially provides the data sets to the room-temperature prediction model RTMⱼ, and repeatedly performs training to change the internal parameter of the room-temperature prediction model RTMⱼ in such a way that a prediction temperature FTⱼ output from the room-temperature prediction model RTMⱼ approaches the measurement temperature MTₘ indicated by the temperature data.

The prediction model generating unit 13 may not provide all the data sets to the room-temperature prediction model RTMⱼ when the prediction accuracy of the room-temperature prediction model RTMⱼ reaches or is beyond the threshold before providing the Q data sets to the room-temperature prediction model RTMⱼ.

The prediction model generating unit 13 continues the machine learning of the room-temperature prediction model RTMⱼ by repeatedly providing the data sets to the room-temperature prediction model RTMⱼ, to thereby generate the room-temperature prediction model RTMⱼ having the prediction accuracy equal to or higher than the threshold (step ST14 in FIG. 5).

The prediction model generating unit 13 outputs the room-temperature prediction model RTMⱼ having the prediction accuracy equal to or higher than the threshold to the operation pattern selecting unit 14.

If there remains no operation pattern OPⱼ in which the operation target air conditioner 1-k is not operated among the J operation patterns OPⱼ (NO in step ST15 in FIG. 5), the operation pattern selecting unit 14 selects one room-temperature prediction model as the room-temperature prediction model RTM_{j,N-3} from among the J room-temperature prediction models RTM₁ to RTM_{J} having prediction accuracy equal to or higher than the threshold.

For example, the operation pattern selecting unit 14 selects one or more room-temperature prediction models RTMⱼ in which the prediction temperature FTⱼ is equal to or lower than the temperature upper limit value Tₘₐₓ from among the J room-temperature prediction models RTM₁ to RTM_{J} having prediction accuracy equal to or higher than the threshold.

Then, the operation pattern selecting unit 14 selects the room-temperature prediction model RTMⱼ having the highest prediction temperature FTⱼ as the room-temperature prediction model RTM_{j,N-3} from among the one or more room-temperature prediction models RTMⱼ having a prediction temperature FTⱼ equal to or lower than the temperature upper limit value Tₘₐₓ.

The operation pattern selecting unit 14 determines the operation pattern OPⱼ corresponding to the selected room-temperature prediction model RTMⱼ as a candidate OP_{SEL,N-3} for the operation pattern (step ST16 in FIG. 5).

Next, if the operation patterns OP₁ to OP_{G} excluding the J operation patterns OP₁ to OP_{J} include the operation pattern OPⱼ in which the number of the operation target air conditioners 1-k is one less than the number of the operation target air conditioners 1-k indicated by the J operation patterns OPⱼ which have been already acquired (YES in step ST17 in FIG. 5), the air conditioner control unit 15 acquires the operation pattern OPⱼ in which the number of the operation target air conditioners 1-k is one less (step ST18 in FIG. 5). For example, if the number of the operation target air conditioners 1-k one less than the largest number is (N−4), and there are J′ operation patterns OPⱼ having (N−4) operation target air conditioners 1-k, the air conditioner control unit 15 acquires J′ operation patterns OPⱼ to OP_{J′}. J′≤G−J is established.

The processes of steps ST12 to ST15 are also repeated for the operation pattern OPⱼ in which the number of the operation target air conditioners 1-k is (N−4).

If there are one or more room-temperature prediction models RTMⱼ having prediction accuracy equal to or higher than the threshold, the operation pattern selecting unit 14 selects the room-temperature prediction model RTMⱼ having the highest prediction temperature FTⱼ as the room-temperature prediction model RTM_{j,N-4} from among the one or more room-temperature prediction models RTMⱼ.

The operation pattern selecting unit 14 determines the operation pattern OPⱼ corresponding to the selected room-temperature prediction model RTMⱼ as a candidate OP_{SEL,N-4} for the operation pattern (step ST16 in FIG. 5).

Afterwards, if the operation patterns OP₁ to OP_{G} excluding the J operation patterns OP₁ to OP_{J} and J′ operation patterns OP₁ to OP_{J′} include the operation pattern OPⱼ in which the number of the operation target air conditioners 1-k is one less than the number of the operation target air conditioners 1-k indicated by the J′ operation patterns OPⱼ which have been already acquired, a candidate for the operation pattern is further determined by a manner similar to the manner described above. Then, a candidate OP_{SEL,N-5} for one operation pattern is selected.

If there is no operation pattern OPⱼ in which the number of the operation target air conditioners 1-k is one less (NO in step ST17 in FIG. 5), the operation pattern selecting unit 14 selects one operation pattern OP_{SEL} from among one or more operation pattern candidates (step ST19 in FIG. 5).

That is, the operation pattern selecting unit 14 selects a candidate for the operation pattern in which the number of the operation target air conditioners 1-k is the smallest from among the one or more operation pattern candidates as one operation pattern OP_{SEL}.

For example, when the candidates for the operation pattern are OP_{SEL,N-3}, OP_{SEL,N-4}, and OP_{SEL,N-5}, the operation pattern selecting unit 14 selects the candidate OP_{SEL,N-5} for the operation pattern as the operation pattern OP_{SEL}.

### Second Embodiment

The second embodiment describes an air conditioning control device 3 including a control amount changing unit 16 that changes a control amount of an operation target air conditioner 1-k indicated by an operation pattern selected by an operation pattern selecting unit 14.

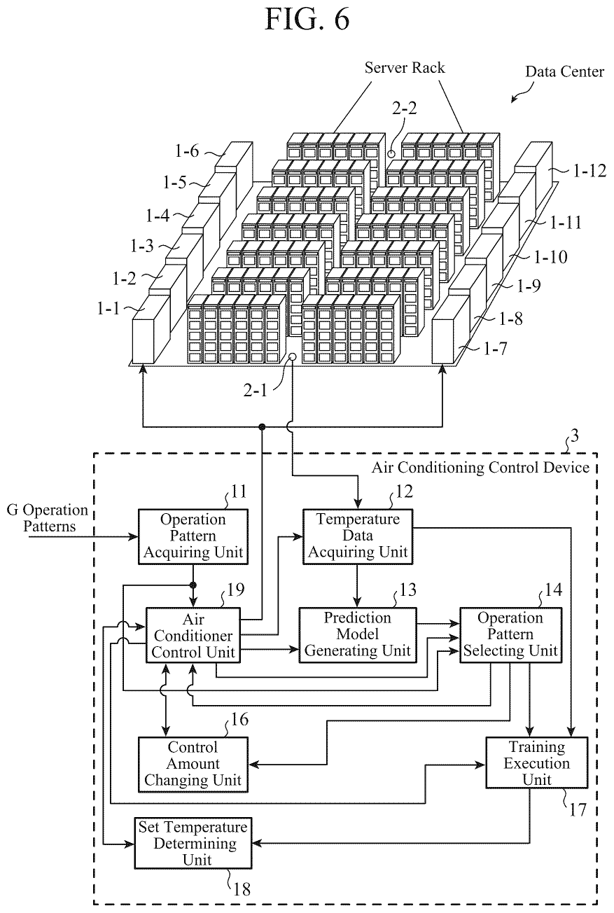

FIG. 6 is a configuration diagram illustrating an air conditioning system including the air conditioning control device 3 according to the second embodiment.

In FIG. 6, elements same as or corresponding to the elements in FIG. 1 are identified by the same reference numerals, and thus, the description thereof will be omitted.

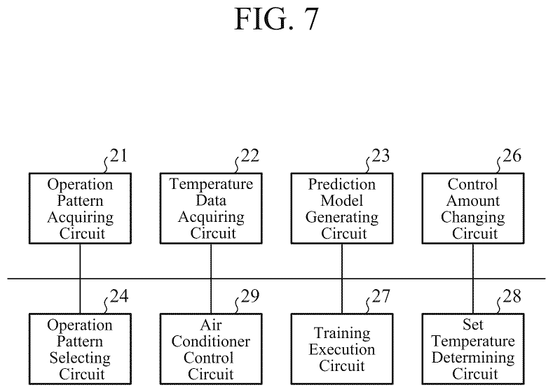

FIG. 7 is a hardware configuration diagram illustrating hardware of the air conditioning control device 3 according to the second embodiment. In FIG. 7, elements same as or corresponding to the elements in FIG. 2 are identified by the same reference numerals, and thus, the description thereof will be omitted.

The air conditioning control device 3 illustrated in FIG. 6 includes an operation pattern acquiring unit 11, a temperature data acquiring unit 12, a prediction model generating unit 13, the operation pattern selecting unit 14, the control amount changing unit 16, a training execution unit 17, a set temperature determining unit 18, and an air conditioner control unit 19.

The control amount changing unit 16 is implemented by, for example, a control amount changing circuit 26 illustrated in FIG. 7.

The control amount changing unit 16 changes a control amount of the operation target air conditioner 1-k indicated by an operation pattern OP_{SEL} selected by the operation pattern selecting unit 14.

In the air conditioning control device 3 illustrated in FIG. 6, the control amount changing unit 16 changes the set temperature PTₖ of the air conditioner 1-k as the control amount of the air conditioner 1-k. However, this is merely an example, and the control amount changing unit 16 may change, as the control amount of the air conditioner 1-k, the air volume of the air conditioner 1-k or the frequency of an operating voltage of a compressor connected to the air conditioner 1-k.

The training execution unit 17 is implemented by, for example, a training execution circuit 27 illustrated in FIG. 7.

The training execution unit 17 acquires the temperature data acquired by the temperature data acquiring unit 12 when the operation target air conditioner 1-k indicated by the operation pattern OP_{SEL} selected by the operation pattern selecting unit 14 is operating, and the set temperature PTₖ that is the control amount changed by the control amount changing unit 16.

The training execution unit 17 provides the acquired temperature data and the changed set temperature PTₖ to the room-temperature prediction model RTM_{g} corresponding to the operation pattern OP_{SEL} selected by the operation pattern selecting unit 14, and trains the room-temperature prediction model RTM_{g} to learn the temperature measured by the temperature sensor 2-m when the operation target air conditioner 1-k indicated by the operation pattern OP_{SEL} is operating.

The set temperature determining unit 18 is implemented by, for example, a set temperature determining circuit 28 illustrated in FIG. 7.

The set temperature determining unit 18 provides, as a tentatively set temperature PTₖ of the air conditioner 1-k, any one of a plurality of temperatures included in a settable temperature range of the air conditioner 1-k to the room-temperature prediction model RTM_{g} that has been trained by the training execution unit 17, and acquires an indoor prediction temperature FT_{g} from the trained room-temperature prediction model RTM_{g}.

The set temperature determining unit 18 determines the set temperature PTₖ of the air conditioner 1-k on the basis of the prediction temperature FT_{g} and the temperature upper limit value Tₘₐₓ.

The air conditioner control unit 19 is implemented by, for example, an air conditioner control circuit 29 illustrated in FIG. 7.

The air conditioner control unit 19 operates the operation target air conditioner 1-k indicated by the operation pattern OP_{SEL} selected by the operation pattern selecting unit 14 at the set temperature PTₖ determined by the set temperature determining unit 18.

FIG. 6 illustrates an example in which each of the operation pattern acquiring unit 11, the temperature data acquiring unit 12, the prediction model generating unit 13, the operation pattern selecting unit 14, the control amount changing unit 16, the training execution unit 17, the set temperature determining unit 18, and the air conditioner control unit 19, which are components of the air conditioning control device 3, is implemented by dedicated hardware as illustrated in FIG. 7. That is, it is assumed that the air conditioning control device 3 is implemented by the operation pattern acquiring circuit 21, the temperature data acquiring circuit 22, the prediction model generating circuit 23, the operation pattern selecting circuit 24, the control amount changing circuit 26, the training execution circuit 27, the set temperature determining circuit 28, and the air conditioner control circuit 29.

Here, each of the operation pattern acquiring circuit 21, the temperature data acquiring circuit 22, the prediction model generating circuit 23, the operation pattern selecting circuit 24, the control amount changing circuit 26, the training execution circuit 27, the set temperature determining circuit 28, and the air conditioner control circuit 29 is, for example, a single circuit, a composite circuit, a programmed processor, a parallel programmed processor, an ASIC, a FPGA, or a combination of some of these circuits.

The components of the air conditioning control device 3 are not limited to be implemented by dedicated hardware, and the air conditioning control device 3 may be implemented by software, firmware, or a combination of software and firmware.

In a case where the air conditioning control device 3 is implemented by software, firmware, or the like, a program for causing a computer to execute the processing procedures performed in the operation pattern acquiring unit 11, the temperature data acquiring unit 12, the prediction model generating unit 13, the operation pattern selecting unit 14, the control amount changing unit 16, the training execution unit 17, the set temperature determining unit 18, and the air conditioner control unit 19 is stored in the memory 31 illustrated in FIG. 3. Then, the processor 32 illustrated in FIG. 3 executes the program stored in the memory 31.

Further, FIG. 7 shows an example in which each of the components of the air conditioning control device 3 is implemented by dedicated hardware, and FIG. 3 shows an example in which the air conditioning control device 3 is implemented by software, firmware, or the like. However, this is merely an example, and some components in the air conditioning control device 3 may be implemented by dedicated hardware, and the remaining components may be implemented by software, firmware, or the like.

Next, the operation of the air conditioning system illustrated in FIG. 6 will be described.

The air conditioning system is similar to the air conditioning system illustrated in FIG. 1 except for the control amount changing unit 16, the training execution unit 17, the set temperature determining unit 18, and the air conditioner control unit 19. Here, operations of the control amount changing unit 16, the training execution unit 17, the set temperature determining unit 18, and the air conditioner control unit 19 will be described.

The control amount changing unit 16 acquires one selected operation pattern OP_{SEL} from the operation pattern selecting unit 14, and acquires the set temperature PTₖ of the air conditioner 1-k as the control amount of the operation target air conditioner 1-k indicated by the operation pattern OP_{SEL} from the air conditioner control unit 19.

The control amount changing unit 16 changes the set temperature PTₖ of the operation target air conditioner 1-k indicated by the operation pattern OP_{SEL}.

For example, the control amount changing unit 16 changes the set temperature PTₖ of the air conditioner 1-k by a method called active learning in order to train the room-temperature prediction model RTM_{g} corresponding to the operation pattern OP_{SEL} to efficiently learn the measurement temperature MTₘ. In the process of changing the set temperature PTₖ by a method called active learning, a temperature farthest from the current set temperature in the settable temperature range of the air conditioner 1-k is determined as the next set temperature, and a temperature farthest from the set temperature that has been determined is further determined as the next set temperature.

An example of changing the set temperature PTₖ by a method called active learning will be specifically described below.

The control amount changing unit 16 calculates a temperature difference ΔPTₖ between each of temperatures other than the set temperature PTₖ that is currently set and the set temperature PTₖ that is currently set among the plurality of temperatures included in the settable temperature range of the air conditioner 1-k.

For example, suppose that a plurality of temperatures included in the settable temperature range is 19 degrees, 20 degrees, 21 degrees, 22 degrees, and 23 degrees, and the currently set temperature PTₖ is 19 degrees.

In this case, the control amount changing unit 16 calculates 1 (=20−19) degree, 2 (=21−19) degrees, 3 (=22−19) degrees, and 4 (=23−19) degrees as the temperature differences ΔPTₖ.

The control amount changing unit 16 selects the changed set temperature PTₖ from the plurality of temperatures included in the temperature range on the basis of the calculated temperature differences ΔPTₖ.

That is, the control amount changing unit 16 specifies the temperature difference ΔPTₖ (=4 degrees) having the maximum absolute value among the plurality of calculated temperature differences ΔPTₖ, and determines 23 degrees, which is the temperature corresponding to the temperature difference ΔPTₖ (=4 degrees) having the maximum absolute value, as the set temperature PTₖ (=23 degrees) after the first change.

Then, the control amount changing unit 16 calculates a temperature difference ΔPTₖ between each of temperatures that have not yet been set as the set temperature PTₖ among the plurality of temperatures included in the settable temperature range of the air conditioner 1-k and the set temperature PTₖ (=23 degrees) after the first change.

The control amount changing unit 16 calculates −3 (=20−23) degrees, −2 (=21−23) degrees, and −1 (=22−23) degrees as the temperature differences ΔPTₖ.

The control amount changing unit 16 specifies the temperature difference ΔPTₖ (=−3 degrees) having the maximum absolute value among the plurality of calculated temperature differences ΔPTₖ, and determines 20 degrees, which is the temperature corresponding to the temperature difference ΔPTₖ (=−3 degrees) having the maximum absolute value, as the set temperature PTₖ (=20 degrees) after the second change.

Then, the control amount changing unit 16 calculates a temperature difference ΔPTₖ between each of temperatures that have not yet been set as the set temperature PTₖ among the plurality of temperatures included in the settable temperature range of the air conditioner 1-k and the set temperature PTₖ (=20 degrees) after the second change.

The control amount changing unit 16 calculates 1 (=21−20) degree and 2 (=22−20) degrees as the temperature differences ΔPTₖ.

The control amount changing unit 16 specifies the temperature difference ΔPTₖ (=2 degrees) having the maximum absolute value among the plurality of calculated temperature differences ΔPTₖ, and determines 22 degrees, which is the temperature corresponding to the temperature difference ΔPTₖ (=2 degrees) having the maximum absolute value, as the set temperature PTₖ (=22 degrees) after the third change.

The control amount changing unit 16 determines 21 degrees, which is a temperature not yet set as the set temperature PTₖ among the plurality of temperatures included in the temperature range, as the set temperature PTₖ (=21 degrees) after the fourth change.

Therefore, the set temperature PTₖ of the air conditioner 1-k is changed as follows.

19 degrees→23 degrees→20 degrees→22 degrees→21 degrees

The control amount changing unit 16 outputs set temperature changing information indicating the detail of the change of the set temperature PTₖ of the air conditioner 1-k to the air conditioner control unit 19.

The set temperature changing information indicates that the set temperature PTₖ is changed in the order of 23 degrees, 20 degrees, 22 degrees, and 21 degrees from 19 degrees.

The air conditioner control unit 19 acquires the set temperature changing information from the control amount changing unit 16, and acquires the operation pattern OP_{SEL} from the operation pattern selecting unit 14.

In order to improve the prediction accuracy of the room-temperature prediction model RTM_{g} corresponding to the operation pattern OP_{SEL}, the air conditioner control unit 19 operates the operation target air conditioner 1-k indicated by the operation pattern OP_{SEL} by switching the set temperature PTₖ of the air conditioner 1-k in the order indicated by the set temperature changing information.

That is, the air conditioner control unit 19 operates the operation target air conditioner 1-k at the set temperature PTₖ (=23 degrees) for a certain period of time, and then operates the air conditioner 1-k at the set temperature PTₖ (=20 degrees) for a certain period of time. Thereafter, the air conditioner control unit 19 operates the operation target air conditioner 1-k at the set temperature PTₖ (=22 degrees) for a certain period of time, and then operates the air conditioner 1-k at the set temperature PTₖ (=21 degrees) for a certain period of time.

Although described in detail later, when the prediction accuracy of the room-temperature prediction model RTM_{g} corresponding to the operation pattern OP_{SEL} reaches high accuracy Aₙₛ when the operation target air conditioner 1-k is operated at, for example, the set temperature PTₖ (=20 degrees) for a certain period of time, the air conditioner control unit 19 does not operate the air conditioner 1-k at the set temperature PTₖ (=22 and 21 degrees). The high accuracy Aₙₛ means that the prediction accuracy of the room-temperature prediction model RTM_{g} is practically satisfactory, and may be, for example, 0.5 degrees or 0.6 degrees.

When operating the operation target air conditioner 1-k at the set temperature PTₖ, the air conditioner control unit 19 outputs the set temperature PTₖ (=23 degrees) after the first change to the training execution unit 17.

When operating the operation target air conditioner 1-k at the set temperature PTₖ (=23 degrees) after the first change, the air conditioner control unit 19 outputs a data acquisition request to the temperature data acquiring unit 12.

The training execution unit 17 acquires one selected operation pattern OP_{SEL} from the operation pattern selecting unit 14.

The training execution unit 17 acquires the set temperature PTₖ (=23 degrees) after the first change from the air conditioner control unit 19.

The training execution unit 17 acquires the temperature data acquired by the temperature data acquiring unit 12 when the operation target air conditioner 1-k indicated by the operation pattern OP_{SEL} is operating at the set temperature PTₖ (=23 degrees) after the first change.

The training execution unit 17 provides the acquired temperature data and set temperature PTₖ (=23 degrees) to the room-temperature prediction model RTM_{g} corresponding to the operation pattern OP_{SEL} to thereby train the room-temperature prediction model RTM_{g} to learn the set temperature PTₖ which is the temperature measured by the temperature sensor 2-m when the operation target air conditioner 1-k indicated by the operation pattern OP_{SEL} is operating. As a result, the prediction accuracy of the room-temperature prediction model RTM_{g} is improved by learning. Thus, the accuracy of the prediction temperature FT_{g} output from the prediction model RTM_{g} is improved.

The training execution unit 17 outputs the prediction accuracy of the room-temperature prediction model RTM_{g} which has been trained to the air conditioner control unit 19.

When the prediction accuracy of the room-temperature prediction model RTM_{g} output from the training execution unit 17 is less than the high accuracy Aₙₛ, the air conditioner control unit 19 operates the operation target air conditioner 1-k at the set temperature PTₖ (=20 degrees) after the second change.

When operating the operation target air conditioner 1-k at the set temperature PTₖ (=20 degrees) after the second change, the air conditioner control unit 19 outputs the set temperature PTₖ (=20 degrees) after the second change to the training execution unit 17.

When operating the operation target air conditioner 1-k, the air conditioner control unit 19 outputs a data acquisition request to the temperature data acquiring unit 12.

When the prediction accuracy of the room-temperature prediction model RTM_{g} output from the training execution unit 17 is equal to or higher than the high accuracy Aₙₛ, the air conditioner control unit 19 does not thereafter operate the air conditioner 1-k for enhancing the prediction accuracy of the room-temperature prediction model RTM_{g}.

The training execution unit 17 acquires the set temperature PTₖ (=20 degrees) after the second change from the air conditioner control unit 19.

The training execution unit 17 acquires the temperature data acquired by the temperature data acquiring unit 12 when the operation target air conditioner 1-k indicated by the operation pattern OP_{SEL} is operating at the set temperature PTₖ (=20 degrees).

The training execution unit 17 provides the acquired temperature data and set temperature PTₖ (=20 degrees) to the room-temperature prediction model RTM_{g} corresponding to the operation pattern OP_{SEL} to thereby train the room-temperature prediction model RTM_{g} to learn the set temperature PTₖ which is the temperature measured by the temperature sensor 2-m when the operation target air conditioner 1-k indicated by the operation pattern OP_{SEL} is operating.

The training execution unit 17 outputs the prediction accuracy of the room-temperature prediction model RTM_{g} which has been trained to the air conditioner control unit 19.

When the prediction accuracy of the room-temperature prediction model RTM_{g} output from the training execution unit 17 is less than the high accuracy Aₙₛ, the air conditioner control unit 19 operates the operation target air conditioner 1-k at the set temperature PTₖ (=22 degrees) after the third change.

When operating the operation target air conditioner 1-k at the set temperature PTₖ (=22 degrees) after the third change, the air conditioner control unit 19 outputs the set temperature PTₖ (=22 degrees) after the third change to the training execution unit 17.

When operating the operation target air conditioner 1-k, the air conditioner control unit 19 outputs a data acquisition request to the temperature data acquiring unit 12.

When the prediction accuracy of the room-temperature prediction model RTM_{g} output from the training execution unit 17 is equal to or higher than the high accuracy Aₙₛ, the air conditioner control unit 19 does not thereafter operate the air conditioner 1-k for enhancing the prediction accuracy of the room-temperature prediction model RTM_{g}.

The training execution unit 17 acquires the set temperature PTₖ (=22 degrees) after the third change from the air conditioner control unit 19.

The training execution unit 17 acquires the temperature data acquired by the temperature data acquiring unit 12 when the operation target air conditioner 1-k indicated by the operation pattern OP_{SEL} is operating at the set temperature PTₖ (=22 degrees).

The training execution unit 17 provides the acquired temperature data and set temperature PTₖ (=22 degrees) to the room-temperature prediction model RTM_{g} corresponding to the operation pattern OP_{SEL} to thereby train the room-temperature prediction model RTM_{g} to learn the set temperature PT which is the temperature measured by the temperature sensor 2-m when the operation target air conditioner 1-k indicated by the operation pattern OP_{SEL} is operating.

The training execution unit 17 outputs the prediction accuracy of the room-temperature prediction model RTM_{g} which has been trained to the air conditioner control unit 19.

When the prediction accuracy of the room-temperature prediction model RTM_{g} output from the training execution unit 17 is less than the high accuracy Aₙₛ, the air conditioner control unit 19 operates the operation target air conditioner 1-k at the set temperature PTₖ (=21 degrees) after the fourth change.

When operating the operation target air conditioner 1-k at the set temperature PTₖ (=21 degrees) after the fourth change, the air conditioner control unit 19 outputs the set temperature PTₖ (=21 degrees) after the fourth change to the training execution unit 17.

When operating the operation target air conditioner 1-k, the air conditioner control unit 19 outputs a data acquisition request to the temperature data acquiring unit 12.

When the prediction accuracy of the room-temperature prediction model RTM_{g} output from the training execution unit 17 is equal to or higher than the high accuracy Aₙₛ, the air conditioner control unit 19 does not thereafter operate the air conditioner 1-k for enhancing the prediction accuracy of the room-temperature prediction model RTM_{g}.

The training execution unit 17 acquires the set temperature PTₖ (=21 degrees) after the fourth change from the air conditioner control unit 19.

The training execution unit 17 acquires the temperature data acquired by the temperature data acquiring unit 12 when the operation target air conditioner 1-k indicated by the operation pattern OP_{SEL} is operating at the set temperature PTₖ (=21 degrees).

The training execution unit 17 provides the acquired temperature data and set temperature PTₖ (=21 degrees) to the room-temperature prediction model RTM_{g} corresponding to the operation pattern OP_{SEL} to thereby train the room-temperature prediction model RTM_{g} to learn the set temperature PTₖ which is the temperature measured by the temperature sensor 2-m when the operation target air conditioner 1-k indicated by the operation pattern OP_{SEL} is operating.

The room-temperature prediction model RTM_{g} is efficiently trained by the training execution unit 17 by changing the set temperature PTₖ of the air conditioner 1-k by a method called active learning. Therefore, it is presumed that the prediction accuracy of the room-temperature prediction model RTM_{g} is equal to or higher than the high accuracy Aₙₛ before all of the plurality of temperatures included in the settable temperature range of the air conditioner 1-k are set as the set temperature PTₖ. Accordingly, the accuracy of the room-temperature prediction model RTM_{B} is improved more quickly by changing the set temperature PTₖ with a method called active learning than by, for example, setting the temperatures included in the settable temperature range as the set temperature PTₖ in the order from a lower to a higher temperature. Therefore, in a case where the set temperature PTₖ is changed by a method called active learning, the time required for training the room-temperature prediction model RTM_{B} is shortened as compared with the case where the temperatures are set as the set temperature PTₖ in the order from a lower to a higher temperature.

The set temperature determining unit 18 determines each of the plurality of temperatures included in the settable temperature range of the air conditioner 1-k as a tentatively set temperature PTₖ′ of the air conditioner 1-k.

The set temperature determining unit 18 provides each of the tentatively set temperatures PTₖ′ to the room-temperature prediction model RTM_{g} that has been trained by the training execution unit 17, and acquires the prediction temperature FT_{g} from each of the trained room-temperature prediction models RTM_{g}.

The set temperature determining unit 18 specifies a prediction temperature FT_{g} equal to or lower than the temperature upper limit value Tₘₐₓ among the plurality of prediction temperatures FT_{g}.

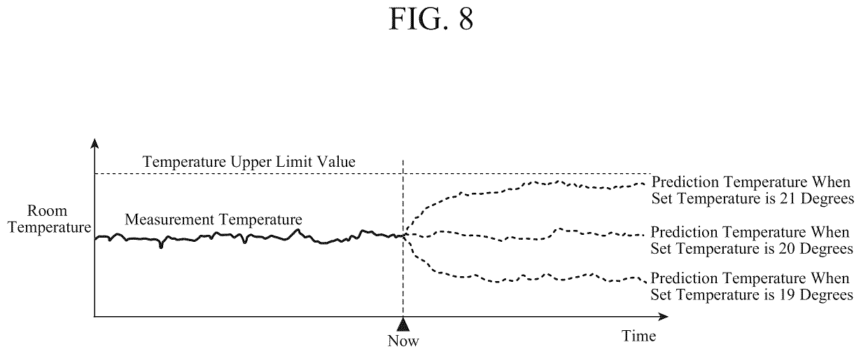

The set temperature determining unit 18 determines the highest temperature among the prediction temperatures FT_{B} equal to or lower than the temperature upper limit value Tₘₐₓ as the set temperature PTₖ of the air conditioner 1-k as illustrated in FIG. 8.

FIG. 8 is an explanatory diagram illustrating candidates for the set temperature PTₖ determined by the set temperature determining unit 18.

In FIG. 8, the horizontal axis indicates a time, and “Now” indicates a current time. The vertical axis represents the indoor temperature.

In the example of FIG. 8, the prediction temperature FT_{g} is equal to or lower than the temperature upper limit value Tₘₐₓ when the tentatively set temperature PTₖ′ is 19 degrees, 20 degrees, and 21 degrees.

The prediction temperature FT_{g} when the tentatively set temperature PTₖ is 21 degrees is the highest temperature among the prediction temperatures FT_{g} when the tentatively set temperature PTₖ′ is 19 degrees, 20 degrees, and 21 degrees, and thus, the set temperature determining unit 18 determines 21 degrees as the set temperature PTₖ of the air conditioner 1-k.

The set temperature determining unit 18 outputs the determined set temperature PTₖ of the air conditioner 1-k to the air conditioner control unit 19.

The air conditioner control unit 19 operates the operation target air conditioner 1-k indicated by the operation pattern OP_{SEL} at the set temperature PTₖ determined by the set temperature determining unit 18.

In the second embodiment described above, the air conditioning control device 3 includes: the control amount changing unit 16 to change the control amount of the operation target air conditioner 1-k indicated by the operation pattern selected by the operation pattern selecting unit 14; and the training execution unit 17 to provide, as training data, the control amount that has been changed by the control amount changing unit 16 and the temperature data acquired by the temperature data acquiring unit 12 when the operation target air conditioner 1-k indicated by the operation pattern selected by the operation pattern selecting unit 14 is in operation to the room-temperature prediction model corresponding to the operation pattern selected by the operation pattern selecting unit 14, and train the room-temperature prediction model to learn the temperature measured by the temperature sensor 2-m when the operation target air conditioner is in operation. Accordingly, the air conditioning control device 3 can determine the air conditioner 1-k to be actually operated among the plurality of air conditioners 1-1 to 1-N without acquiring layout data, and further, can change the control amount of the operation target air conditioner 1-k.

In addition, in the second embodiment, the control amount of the operation target air conditioner 1-k is a set temperature of the air conditioner 1-k, and the air conditioning control device 3 includes the set temperature determining unit 18 to provide, to the room-temperature prediction model that has been trained by the training execution unit 17, any of a plurality of temperatures included in a settable temperature range of the air conditioner 1-k as a tentatively set temperature of the air conditioner 1-k to acquire a prediction temperature from the room-temperature prediction model that has been trained, and determine the set temperature of the air conditioner 1-k on the basis of the prediction temperature and the temperature upper limit value. With this configuration, the air conditioning control device 3 can determine the set temperature at which the power consumption can be reduced within a range in which the indoor temperature does not exceed the temperature upper limit value.

In the air conditioning control device 3 illustrated in FIG. 6, the control amount changing unit 16 changes the set temperature PTₖ of the air conditioner 1-k by a method called active learning.

The process of changing the set temperature PTₖ by a method called active learning is not limited to determine a temperature farthest from the current set temperature in the settable temperature range of the air conditioner 1-k as the next set temperature, and the control amount changing unit 16 may determine the next set temperature as follows.

The control amount changing unit 16 obtains an evaluation value indicating the accuracy of the room-temperature prediction model RTM_{g} with respect to each set temperature PTₖ when each of the plurality of temperatures included in the settable temperature range of the air conditioner 1-k is set to the set temperature PTₖ using Bayesian optimization, for example. The evaluation value is larger as the accuracy of the room-temperature prediction model RTM_{g} with respect to the set temperature PTₖ is higher. Since the Bayesian optimization is a known technique, the detailed description thereof will be omitted. When, for example, evaluation values indicating the accuracy of the room-temperature prediction models RTM_{g} with respect to two set temperatures PTₖ are known in a case where the Bayesian optimization is used, evaluation values indicating the accuracy of the room-temperature prediction models RTM_{g} with respect to the remaining set temperatures PTₖ are obtained.

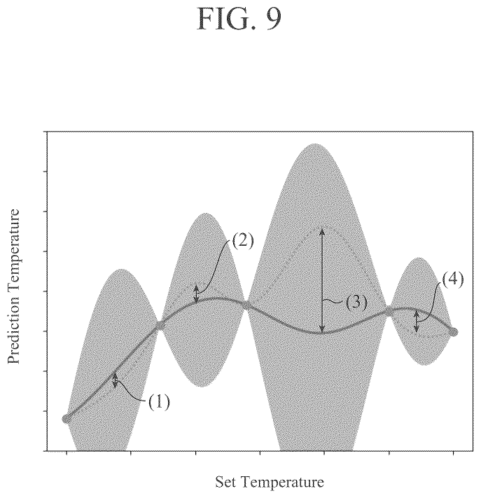

FIG. 9 is an explanatory diagram illustrating accuracy of the room-temperature prediction model RTM_{g} with respect to the set temperature PTₖ.

In FIG. 9, ● indicates the set temperature PTₖ that has been set. A solid line indicates a prediction temperature FT_{g} which is an output temperature of the room-temperature prediction model RTM_{g} with respect to the set temperature PTₖ, and a dotted line indicates a true value of the prediction temperature FT_{g}.

The interval between the solid line and the dotted line represents an evaluation value indicating the accuracy of the room-temperature prediction model RTM_{g} with respect to the set temperature PTₖ. The lengths of arrows (1) to (4) indicate the interval between the solid line and the dotted line. The narrower the interval between the solid line and the dotted line, the higher the evaluation value. In the example of FIG. 9, length of arrow (1)<length of arrow (2)<length of arrow (4)<length of arrow (3). In the drawing, the gray area indicates an area in which the reliability of the room-temperature prediction model RTM_{g} is about 95%.

The control amount changing unit 16 compares evaluation values indicating the accuracy of the room-temperature prediction models RTM_{g} with respect to temperatures that have not yet been set as the set temperature PTₖ among the plurality of temperatures included in the settable temperature range of the air conditioner 1-k.

If the temperatures that have not yet been set as the set temperature PTₖ are, for example, the temperatures corresponding to the arrows (1) to (4), the lengths of the arrows (1) to (4) are compared with each other.

The control amount changing unit 16 determines the temperature having the smallest evaluation value as the next set temperature PTₖ, and further determines the temperature having the second smallest evaluation value as the set temperature PTₖ next to the immediately preceding set temperature PTₖ on the basis of the comparison result of the evaluation values. Thereafter, the control amount changing unit 16 determines the set temperatures PTₖ in ascending order of evaluation values.

In the example of FIG. 9, the control amount changing unit 16 first determines the temperature corresponding to the arrow (3) having the smallest evaluation value as the next set temperature PTₖ, and determines the temperature corresponding to the arrow (4) having the second smallest evaluation value as the set temperature PTₖ next to the immediately preceding set temperature PTₖ. The control amount changing unit 16 determines the temperature corresponding to the arrow (2) having the third smallest evaluation value as the set temperature PTₖ next to the immediately preceding set temperature PTₖ, and in the end, determines the temperature corresponding to the arrow (1) having the largest evaluation value as the set temperature PTₖ next to the immediately preceding set temperature PTₖ.

Even when the control amount changing unit 16 determines the next set temperature as described above, the room-temperature prediction model RTM_{g} is effectively trained to learn the measurement temperature MTₘ.

In the example of FIG. 9, the control amount changing unit 16 determines the set temperature PTₖ in order of the length of arrow. However, this is merely an example, and the control amount changing unit 16 may preferentially determine the temperature included in a large gray area as the set temperature PTₖ.

In FIG. 9, the control amount changing unit 16 determines, for example, the temperature corresponding to the arrow (2) as the set temperature PTₖ before the temperature corresponding to the arrow (1). However, the control amount changing unit 16 may determine the temperature corresponding to the arrow (1) as the set temperature PTₖ before the temperature corresponding to the arrow (2) on the basis of the size of the gray area.

In the air conditioning control device 3 illustrated in FIG. 6, the training execution unit 17 trains the operation pattern OP_{SEL} selected by the operation pattern selecting unit 14 to learn the temperature measured by the temperature sensor 2-m, and then, the air conditioner control unit 19 operates the operation target air conditioner 1-k indicated by the trained operation pattern OP_{SEL} at the set temperature PTₖ determined by the set temperature determining unit 18. However, the operation pattern OP_{SEL} selected by the operation pattern selecting unit 14 may be changed depending on a change in an operation mode or the like of an electronic device installed in a data center or the like. In such a case, the training execution unit 17 may train the changed operation pattern OP_{SEL} to learn the temperature measured by the temperature sensor 2-m.

It is to be noted that, in the present disclosure, any embodiments can be freely combined to each other, or any component in the embodiments can be modified or omitted.

### INDUSTRIAL APPLICABILITY

The air conditioning control device according to the present disclosure can be used for air-conditioning control of a server room or the like, for example.

### REFERENCE SIGNS LIST

1-1 to 1-12: air conditioner, 2-1 to 2-2: temperature sensor, 3: air conditioning control device, 11: operation pattern acquiring unit, 12: temperature data acquiring unit, 13; prediction model generating unit, 14: operation pattern selecting unit, 15: air conditioner control unit, 16: control amount changing unit, 17: training execution unit, 18: set temperature determining unit, 19: air conditioner control unit, 21: operation pattern acquiring circuit, 22: temperature data acquiring circuit, 23: prediction model generating circuit, 24: operation pattern selecting circuit, 25: air conditioner control circuit, 26: control amount changing circuit, 27: training execution circuit, 28: set temperature determining circuit, 29: air conditioner control circuit, 31: memory, 32: processor

1. An air conditioning control device comprising processing circuitry
to acquire a plurality of operation patterns each indicating at least one operation target air conditioner among a plurality of air conditioners installed in a room,
to acquire temperature data indicating a measurement temperature of a temperature sensor installed in the room when the at least one operation target air conditioner indicated by each of the plurality of operation patterns is in operation,
to generate, using a control amount of the at least one operation target air conditioner indicated by each of the plurality of operation patterns and the temperature data when the at least one operation target air conditioner is in operation as training data, a room-temperature prediction model, which corresponds to each of the plurality of operation patterns, for predicting a temperature measured by the temperature sensor when the at least one operation target air conditioner indicated by each of the plurality of operation patterns is in operation, and
to acquire a prediction temperature from the room-temperature prediction model by providing the control amount of the at least one operation target air conditioner indicated by each of the plurality of operation patterns to the room-temperature prediction model, and selects one operation pattern from the plurality of operation patterns on a basis of the prediction temperature.

2. The air conditioning control device according to claim 1, wherein the processing circuitry further performs to operate the at least one operation target air conditioner indicated by the operation pattern selected.

3. The air conditioning control device according to claim 1, wherein the processing circuitry further performs to select, with respect to each of the plurality of operation patterns, at least one operation pattern in which the prediction temperature obtained from the room-temperature prediction model corresponding to said each of the plurality of operation patterns is equal to or lower than a temperature upper limit value and prediction accuracy of the room-temperature prediction model corresponding to said each of the plurality of operation patterns is within a threshold, and selects, from the at least one operation pattern selected, the ne operation pattern in which the number of the at least one operation target air conditioner is relatively small.

4. The air conditioning control device according to claim 1, wherein the processing circuitry further performs to change the control amount of the at least one operation target air conditioner indicated by the one operation pattern selected, and
to train the room-temperature prediction model to learn the temperature measured by the temperature sensor when the at least one operation target air conditioner is in operation by providing, as training data, the control amount that has been changed and the temperature data when the at least one operation target air conditioner indicated by the one operation pattern selected is in operation to the room-temperature prediction model corresponding to the one operation pattern.

5. The air conditioning control device according to claim 4, wherein
the control amount of the at least one operation target air conditioner is a set temperature of the at least one operation target air conditioner, and
the processing circuitry further performs to calculate temperature differences between a plurality of temperatures included in a settable temperature range of the at least one operation target air conditioner and a current set temperature that is currently set, and determine an order of setting the plurality of temperatures to the set temperature on a basis of the temperature differences that have been calculated, and
to provide the plurality of temperatures to the room-temperature prediction model corresponding to the one operation pattern selected in time order from an earlier time to a later time and train the room-temperature prediction model to learn the temperature measured by the temperature sensor when the at least one operation target air conditioner is in operation.

6. The air conditioning control device according to claim 4, wherein
the control amount of the at least one operation target air conditioner is a set temperature of the at least one operation target air conditioner, and
the processing circuitry further performs to acquire a prediction temperature from the room-temperature prediction model that has been trained by providing, to the room-temperature prediction model that has been trained, one of a plurality of temperatures included in a settable temperature range of the at least one operation target air conditioner as a tentatively set temperature of the at least one operation target air conditioner, and determine the set temperature of the at least one operation target air conditioner on a basis of the prediction temperature and a temperature upper limit value.

7. The air conditioning control device according to claim 6, wherein the processing circuitry further performs to operate the at least one operation target air conditioner indicated by the operation pattern selected at the set temperature.

8. An air conditioning control method comprising:
acquiring a plurality of operation patterns each indicating at least one operation target air conditioner among a plurality of air conditioners installed in a room;
acquiring temperature data indicating a measurement temperature of a temperature sensor installed in the room when the at least one operation target air conditioner indicated by each of the plurality of operation patterns is in operation;
generating using a control amount of the at least one operation target air conditioner indicated by each of the plurality of operation patterns and the temperature data when the at least one operation target air conditioner is in operation as training data, a room-temperature prediction model, which corresponds to each of the plurality of operation patterns, for predicting a temperature measured by the temperature sensor when the at least one operation target air conditioner indicated by each of the plurality of operation patterns is in operation; and
acquiring a prediction temperature from the room-temperature prediction model by providing the control amount of the at least one operation target air conditioner indicated by each of the plurality of operation patterns to the room-temperature prediction model, and selecting one operation pattern from the plurality of operation patterns on a basis of the prediction temperature.
